(19) United States
(12) Patent Application Publication
(10) Pub. No.: US 2007/0063714 A1
(43) Pub. Date: Mar. 22, 2007

(54) High bandwidth probe

(76) Inventor: Michael T. McTigue, Colorado Springs, CO (US)

Correspondence Address: AGILENT TECHNOLOGIES INC., INTELLECTUAL PROPERTY ADMINISTRATION,LEGAL DEPT., MS BLDG. E P.O. BOX 7599, LOVELAND, CO, 80537, US

(21) Appl. No.: 11/231,721

(22) Filed: Sep. 21, 2005

(51) Int. Cl. G01R 31/02

(52) U.S. Cl. 324/754

(57) ABSTRACT

A probe head provides an electrical signal to a receiving device. The probe head has a probe tip and a signal-ground transport element and the signal-ground transport element is configured to provide inherent spring properties.

### BACKGROUND

An existing difficulty with high bandwidth voltage probes is minimizing connection parasitics in a probe that also offers high usability. Typically, the quality of an electrical connection made with a high bandwidth voltage probe to a test point during manual probing is very susceptible to slight operator movement. Any hand or body movement by the operator can either degrade or break the electrical connection. Accordingly, a desirable usability feature is a certain amount of multi-axis compliance in order to allow normal hand movement that occurs when a user tries to maintain contact between the probe and a test point. Because manual probes must be designed for multiple applications, another desirable usability feature is variable span between the two signal connections. Because high frequency probes are used to access high frequency circuits, it is further desirable to minimize the physical bulk of the probe in order to properly access test points within the small geometries that are typically associated with high frequency devices.

Existing probes address the variable span and z-axis compliance usability features by having a separate flexible shaped ground accessory with a spring wire or spring pogo. The separate ground accessory permits a stationary ground while the other connection moves. In this solution, z-axis compliance is available only on the ground connection.

Existing differential probes use integrated pin sockets at the tip of the probe. A user inserts either straight pins or bent wire pins to permit connection to the test points being probed. Bent wire pins permit variable spacing. Flexibility in the wire provides some z-axis compliance, but the bandwidth that uses this solution is limited. Some existing differential probes with higher bandwidth use fixed spacing and no z-axis compliance. Features that provide variable span increase the connection parasitics thereby degrading the probe bandwidth. Another existing high bandwidth differential probe is disclosed in U.S. Pat. No. 6,828,768 (herein “the '768 patent”). The '768 patent teaches a variable span design and multi-axis compliance. Variable span is achieved through use of rotating offset tips. Multi-axis compliance is achieved through use of twin spring loaded probe cylinders. While the teachings of the '768 patent provide a high bandwidth probe with variable span and multi-axis compliance, it does so at the cost of some complexity. The probe body in an embodiment of the '768 patent is relatively large and the complexity presents a challenge to further scale down the geometry of the probe.

There remains a need, therefore, for a high bandwidth probe with variable span, multi-axis compliance that is capable of probing small device geometries.

### BRIEF DESCRIPTION OF THE DRAWINGS

An understanding of the present teachings can be gained from the following detailed description, taken in conjunction with the accompanying drawings of which:

FIG. 1 is a perspective view of an embodiment of a differential probe head according to the present teachings.

FIG. 2 is an enlarged perspective view of an embodiment of the probe tips of the differential probe head as shown in FIG. 1 of the drawings.

FIG. 3 is a perspective view of an embodiment of a component of a probe head according to the present teachings.

FIG. 4 is a front plan view of an embodiment of a probe head according to the present teachings.

FIG. 5 is a side plan view of the embodiment of the component of the probe head shown in FIG. 3.

FIG. 6 is a front plan view of an alternative embodiment of a probe head according to the present teachings.

FIG. 7 is a front plan view of an alternative embodiment of a probe head according to the present teachings.

### DETAILED DESCRIPTION

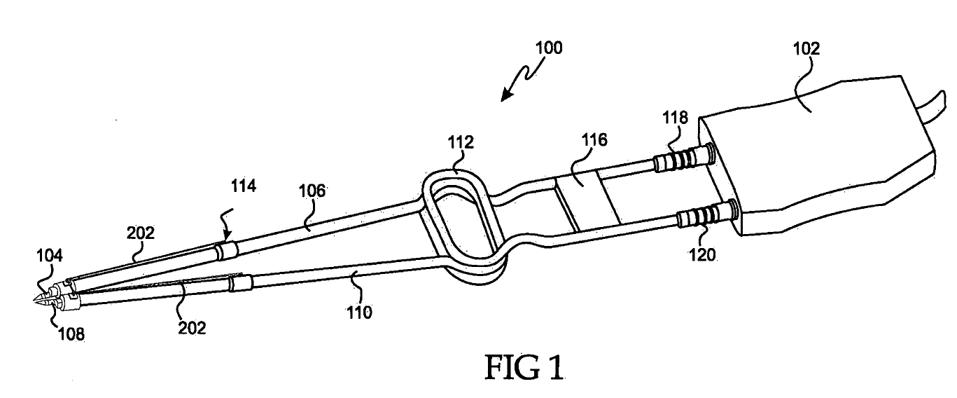

With specific reference to FIG. 1 of the drawings, there is shown a perspective view of an embodiment of a differential probe head 100 according to the present teachings for connection to probe amplifier 102. The probe head 100 contacts test points on a device or system being probed (not shown) and provides electrical signal to the probe amplifier 102 for presentation to a receiving device, such as an oscilloscope (not shown). The probe head 100 according to the present teachings is slender through its body, which enhances the ability to access small areas and does not unduly hinder a user's view of the test points being probed. The slender probe head 100 also permits use of multiple probe heads to access multiple test points that are relatively close together. In the specific embodiment illustrated, a housing of the amplifier 102 is the handle of a browser system, which places a user's hand some distance away from the test points being probed reducing crowding and further permitting unobstructed view of the test points.

A specific embodiment of the probe amplifier 102 suitable for use in the browser system according to the present teachings is the High Bandwidth InfiniiMax probe amplifier available from Agilent Technologies, Inc. The probe amplifier 102 has first and second amplifier connectors to receive first and second mating connectors 118, 120 disposed at an end of the probe head 100. In a specific embodiment, the first and second connectors 118, 120 are GPO/SMP connectors. Other suitable connectors are within the scope of the present teachings. Selection of a suitable connector style is dictated in part by connector size, frequency bandwidth of the signals being transmitted between the probe head 100 and the probe amplifier 102, and other practical considerations. The probe head 100 is separable from the probe amplifier 102 to allow use of multiple styles of probe head 100 for a single probe amplifier 102 rendering a browser system less expensive and more repairable than if the probe head 100 and probe amplifier 102 were unitary.

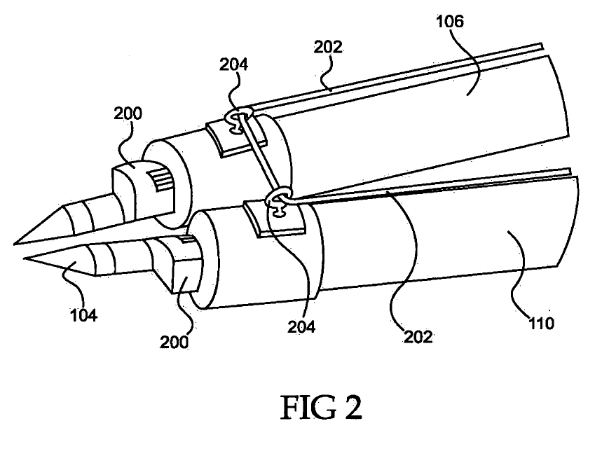

A specific embodiment of the probe head 100 has at least one signal-ground transport element 106 comprising a length of semi-rigid coaxial transmission line. A probe tip 104 is connected at a distal end of the signal-ground transport element 106 for probing test points of the device under test. In a specific embodiment, the probe tip 104 is replaceable. Because the probe tip 104 tends to be one of the more fragile elements in the probe head 100, the replaceable probe tip 104 reduces a cost of probe head repair. In certain embodiments of the probe head 100 and with specific reference to FIG. 2 of the drawings, an impedance element 200 is disposed at the probe tip 104. The impedance element 200 may be any suitable discrete impedance or impedance network disposed between the probe tip 104 and the signal of the signal-ground transport element 106. In a specific embodiment, the impedance element 200 is a resistive element or a resistive-capacitive element depending upon the desired signal conditioning and bandwidth requirements.

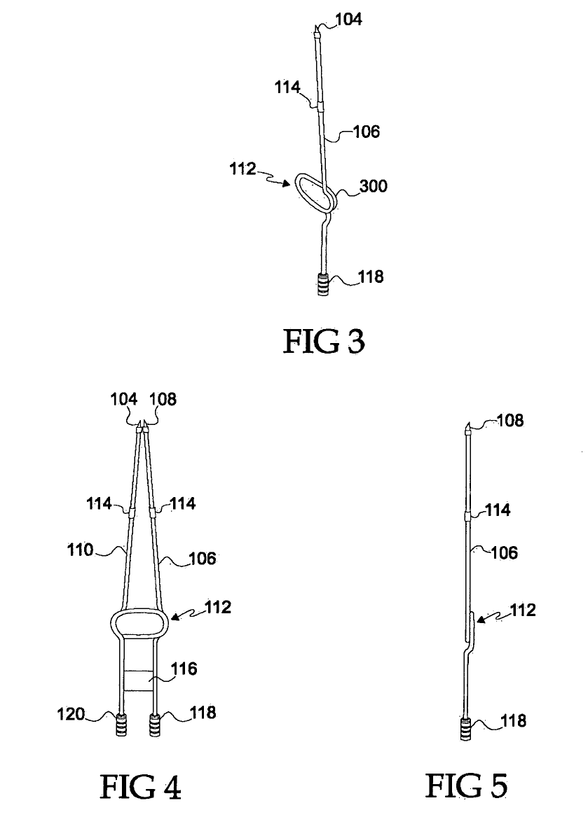

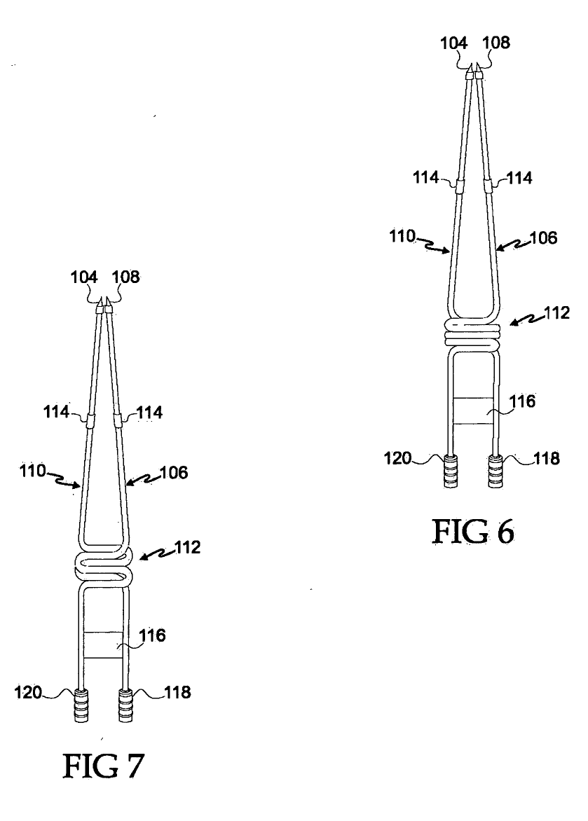

With specific reference to FIG. 3 of the drawings, the signal-ground transport element 106 is configured to provide inherent spring properties over its length. A subset along the length of the signal-ground transport element 106 is configured into a spring portion 112 of the probe head 100. The spring portion 112 is disposed between the probe tip 104 and the connector 118. Accordingly, the spring portion 112 serves to provide the inherent spring properties in the probe head 100 as well as serve as part of the signal-ground transport element 106. Pressure placed in the probe tip 104 results in some give within the spring portion 112 permitting some compliance to maintain contact with a test point in the presence of normal hand movements. In a specific embodiment, the spring portion 112 is bent into a generally planar loop 300 that is parallel to the signal-ground transport element 106. A radius of the bends in the microcoax that make the loop 300 is no smaller than a minimum bend radius for the microcoax so that it does not affect the bandwidth of the signal-ground transport 106. Other embodiments providing for inherent spring properties include a helix as shown in FIG. 6 of the drawings and a planar curvilinear element as shown in FIG. 7 of the drawings. Other shapes that provide inherent spring properties are also contemplated by the present teachings. In a specific embodiment, the signal-ground transport element 106 is made from a length of semi-rigid micro-coaxial cable. A length of the semi-rigid micro-coax is long enough to provide a slender taper in addition to the shape that provides the inherent spring properties, but not so long that the probe head becomes awkward to maintain connection with the probed test point. A range of appropriate lengths may be anywhere from 1.5 inches to 4 inches using currently known materials. Other materials currently know or that may become known in the future may support differing lengths depending upon rigidity of the material and the needs of any specific application. The diameter of the semi-rigid coax affects the spring properties of the probe head and different properties may be appropriate in certain applications. A specific embodiment considered useful for many applications uses a semi-rigid micro-coax having a 0.047 inch diameter. A larger diameter semi-rigid micro-coax, for example 0.086 inches, is stiffer and provides less give in its spring portion 112 than embodiments with smaller diameters. A smaller diameter semi-rigid micro-coax, for example 0.020 inches, is less stiff and is more fragile, but provides more range of movement in its spring portion. Other lengths and diameters are also suitable depending upon the desired configuration of the spring portion, the design and configuration of which are within the capabilities of one of ordinary skill in the art given benefit of the present teachings.

Referring to FIG. 1 of the drawings, in a specific embodiment of a differential probe head, the probe head 100 comprises two identically configured first and second probe tips 104, 108 and first and second signal-ground transport elements 106, 110 held together with a tie bar 116. In this configuration, the spring portion 112 on each probe tip 104, 108 aligns and is in the same position along the length of the probe head 100. In a specific embodiment, two sliders 114 each comprise a single sleeve, one sleeve disposed on each signal-ground transport element 106, 110 to travel along the length of the signal-ground transport element 106, 110 between the probe tip 104, 108 and the spring portion 112. Distal ends of a ground wire 202 are attached to each slider 114. With specific reference to FIG. 2 of the drawings that shows a more detailed view of a probe tip end of the probe head, a retention loop 204 is disposed close to each probe tip 104 and makes electrical contact to respective grounds of the signal-ground transport elements 106, 110. The ground wire 202 extends from one of the sliders 114 through the two retention loops 204 and to the other slider 114. In one aspect according to the present teachings, the ground wire 202 provides probe tip 104 to probe tip 104 electrical grounding. As one of ordinary skill in the art appreciates, the close proximity of the probe tip 104 to ground 202 decreases the signal to ground loop distance, which decreases parasitic impedances and allows for high bandwidth transmission through the signal-ground transport elements 106, 110. In a specific embodiment according to the present teachings, the signal-ground transport elements 106, 110 are spaced a fixed distance from each other. Specifically, the probe tip 104 to probe tip 104 spacing is approximately 3 inches. The sliders 114 may be variably positioned along respective signal-ground transport elements. Depending upon where the sliders 114 are positioned along the signal-ground transport elements 106, 110, the portion of ground wire 202 that extends between the two retention loops 204 shortens or lengthens the retention loop 204 to retention loop 204 spacing. As the portion that extends between the two retention loops 204 shortens, it brings the probe tips 104, 108 together thereby reducing the probe tip 104 to probe tip 108 spacing. As the portion that extends between the two retention loops 204 lengthens, it permits the probe tips 104, 108 to approach or return to their original spacing. Accordingly, the sliders 114 attached to the ground wire 202 serve to ground the ground portion of the signal-ground transport elements 106, 110 close to the probe tips 104, 108 as well as provide steady probe tip 104 to probe tip 108 spacing.

Certain embodiments according to the present teachings are described herein for purposes of illustration. Other embodiments not specifically mentioned will occur to one of ordinary skill with benefit of the present teachings even though they are not specifically described and are considered to be within the scope of the appended claims. Therefore, embodiments and illustrations herein are meant to be illustrative and the scope of the present teachings is limited only by the appended claims.

1. An apparatus comprising:
a probe head having a probe tip and a signal-ground transport element for presentation of a probed signal to a receiving device, the signal-ground transport element configured to provide inherent spring properties.

2. An apparatus as recited in claim 1, the probe tip and signal-ground transport being a first probe tip and first signal-ground transport, respectively, the probe head further comprising a second probe tip and a second signal-ground transport element, the second signal-ground transport element configured to provide inherent spring properties.

3. An apparatus as recited in claim 2 wherein the first and second signal-ground transports have substantially the same configuration.

4. An apparatus as recited in claim 1 wherein the signal-ground transport comprises a micro-coaxial line having a portion configured as a loop.

5. An apparatus as recited in claim 4 wherein the loop is planar.

6. An apparatus as recited in claim 4 wherein the loop includes a radius no smaller than a bend radius limit of the micro-coaxial line.

7. An apparatus as recited in claim 1 wherein the signal-ground transport comprises a micro-coaxial line configured as a helix.

8. An apparatus as recited in claim 7 wherein the helix includes a radius no smaller than a bend radius limit of the micro-coaxial line.

9. An apparatus as recited in claim 1 wherein the signal ground transport comprises a micro-coaxial line configured with a curvilinear portion.

10. An apparatus as recited in claim 2 and further comprising a ground mechanism that interconnects grounds of the first and second signal-ground transport elements.

11. An apparatus as recited in claim 10 wherein the ground mechanism slides along the first and second signal-ground transports elements to adjust a distance between the first probe tip and the second probe tip.

12. An apparatus as recited in claim 1 wherein an amplifier is disposed between the signal-ground transport element and the receiving device.

13. A probe head apparatus for connection to an amplifier comprising:
First and second signal-ground transport elements disposed in fixed relationship to each other, each signal-ground transport element having a probe tip, each signal-ground transport element configured to provide inherent spring properties.

14. An apparatus as recited in claim 13 wherein the first and second signal-ground transports have substantially the same configuration.

15. An apparatus as recited in claim 13 wherein the signal-ground transport comprises a micro-coaxial line having a portion configured as a loop.

16. An apparatus as recited in claim 15 wherein the loop is planar.

17. An apparatus as recited in claim 15 wherein the loop includes a radius no smaller than a bend radius limit of the micro-coaxial line.

18. An apparatus as recited in claim 13 wherein the signal-ground transport comprises a micro-coaxial line configured as a helix.

19. An apparatus as recited in claim 18 wherein the helix includes a radius no smaller than a bend radius limit of the micro-coaxial line.

20. An apparatus as recited in claim 13 wherein the signal ground transport comprises a micro-coaxial line configured with a curvilinear portion.

21. An apparatus as recited in claim 13 and further comprising a ground mechanism that interconnects grounds of the first and second signal-ground transport elements.

22. An apparatus as recited in claim 21 wherein the ground mechanism slides along the first and second signal-ground transports elements to adjust a distance between the first probe tip and the second probe tip.
